(19) United States
(12) Patent Application Publication
(10) Pub. No.: US 2023/0205334 A1
(43) Pub. Date: Jun. 29, 2023

(54) TOUCH DISPLAY MODULE

(71) Applicant: TPK Touch Solutions (Xiamen) Inc., Xiamen (CN)

(72) Inventors: Zhi Juan LIN, Zhangzhou City (CN); Ching-Kai CHO, Changhua County (TW); Ting Ying LIU, Xiamen City (CN)

(21) Appl. No.: 17/565,010

(22) Filed: Dec. 29, 2021

(51) Int. Cl. G06F 3/041; H01L 27/32; H01L 51/52

(52) U.S. Cl. CPC G06F 3/0412; H01L 27/323; H01L 51/5246; H01L 51/5293

(57) ABSTRACT

A touch display module including a cover plate, a first adhesive layer, a thin glass layer, a second adhesive layer, a touch sensing layer, a third adhesive layer, a polarizing film, and an organic light emitting display layer is provided. A thickness of the cover plate is from 50 μm to 70 μm. A thickness of the first adhesive layer is from 40 μm to 60 μm. A thickness of the thin glass layer is from 40 μm to 80 μm. A thickness of the second adhesive layer is from 10 μm to 60 μm. A thickness of the touch sensing layer is from 28 μm to 48 μm. A plane located at half of a total thickness of the touch display module is defined as a stress neutral layer located in the touch sensing layer, third adhesive layer, polarizing film, or organic light emitting display layer.

### BACKGROUND

### Field of Disclosure

The present disclosure relates to a touch display module.

### Description of Related Art

In recent years, the demand for wearable electronic devices has increased, which in turn has driven the demand for rollable touch display modules. However, during the process of bending the touch display module, excessive stress usually accumulates, resulting in damage to components (such as circuits) in the touch display module, which limits the development of the rollable touch display module.

For the foregoing reason, there is a need to solve the above-mentioned problem by providing a rollable touch display module.

### SUMMARY

Some embodiments of the present disclosure provide a touch display module including a cover plate, a first adhesive layer, a thin glass layer, a second adhesive layer, a touch sensing layer, a third adhesive layer, a polarizing film, and an organic light emitting display layer. A thickness of the cover plate is from 50 μm to 70 μm. The first adhesive layer is disposed under the cover plate. A thickness of the first adhesive layer is from 40 μm to 60 μm. The thin glass layer is disposed under the first adhesive layer. A thickness of the thin glass layer is from 40 μm to 80 μm. The second adhesive layer is disposed under the thin glass layer. A thickness of the second adhesive layer is from 10 μm to 60 μm. The touch sensing layer is disposed under the second adhesive layer. A thickness of the touch sensing layer is from 28 μm to 48 μm. The touch sensing layer has an upper surface and a lower surface opposite to the upper surface. The third adhesive layer is disposed under the touch sensing layer. A thickness of the third adhesive layer is from 40 μm to 60 μm. The polarizing film is disposed under the third adhesive layer. A thickness of the polarizing film is from 36 μm to 76 μm. The organic light emitting display layer is disposed under the polarizing film. A thickness of the organic light emitting display layer is from 40 μm to 60 μm. A plane located at half of the touch sensing layer is defined as a center plane. The center plane is parallel to the upper surface and the lower surface, and the touch sensing layer is located at half of a total thickness of the touch display module.

In the foregoing, Young's modulus of the thin glass layer is greater than 65000 million pascals.

In the foregoing, a plane located at half of the total thickness of the touch display module is defined as a stress neutral layer, and a vertical distance between the stress neutral layer and the center plane is less than half of the thickness of the touch sensing layer.

In the foregoing, the thickness of the thin glass layer is from 60 μm to 80 μm, and the thickness of the second adhesive layer is from 10 μm to 35 μm.

In the foregoing, the thickness of the thin glass layer is from 40 μm to 60 μm, and the thickness of the second adhesive layer is from 36 μm to 60 μm.

In the foregoing, the touch display module further includes a support layer, a fourth adhesive layer, and a substrate. The support layer is disposed under the organic light emitting display layer, and a thickness of the support layer is from 28 μm to 85 μm. The fourth adhesive layer is disposed under the support layer, and a thickness of the fourth adhesive layer is from 40 μm to 60 μm. The substrate is disposed under the fourth adhesive layer, and a thickness of the substrate is from 20 μm to 40 μm.

In the foregoing, the Poisson's ratio of the thin glass layer is less than 0.3.

In the foregoing, a time constant of a resistor-capacitor of the touch sensing layer is less than 1400 nanoseconds.

Some embodiments of the present disclosure provide a touch display module including a thin glass layer, a first adhesive layer, a touch sensing layer, a second adhesive layer, a polarizing film, an organic light emitting display layer, a support layer, a third adhesive layer, and a substrate. A thickness of the thin glass layer is 50 μm. The first adhesive layer is disposed under the thin glass layer. A thickness of the first adhesive layer is 50 μm. The touch sensing layer is disposed under the first adhesive layer. A thickness of the touch sensing layer is 38 μm. The touch sensing layer has an upper surface and a lower surface opposite to the upper surface. The second adhesive layer is disposed under the touch sensing layer. A thickness of the second adhesive layer is 50 μm. The polarizing film is disposed under the second adhesive layer. A thickness of the polarizing film is 46 μm. The organic light emitting display layer is disposed under the polarizing film. A thickness of the organic light emitting display layer is 35 μm. The support layer is disposed under the organic light emitting display layer. A thickness of the support layer is 38 μm. The third adhesive layer is disposed under the support layer. A thickness of the third adhesive layer is 50 μm. The substrate is disposed under the third adhesive layer. A thickness of the substrate is 30 μm. A plane located at half of the thickness of the touch sensing layer is defined as a center plane. The center plane is parallel to the upper surface and the lower surface, and the polarizing film is located at half of a total thickness of the touch display module.

In the foregoing, Young's modulus of the thin glass layer is greater than 65000 million pascals.

In the foregoing, a plane located at half of the total thickness of the touch display module is defined as a stress neutral layer, and a vertical distance between the stress neutral layer and the center plane is less than twice the thickness of the touch sensing layer.

Some embodiments of the present disclosure provide a touch display module including a cover plate, a first adhesive layer, a touch sensing layer, a second adhesive layer, a polarizing film, an organic light emitting display layer, a support layer, a third adhesive layer, and a substrate. A thickness of the cover plate is 50 μm. The first adhesive layer is disposed under the cover plate. A thickness of the first adhesive layer is 50 μm. The touch sensing layer is disposed under the first adhesive layer. A thickness of the touch sensing layer is 38 μm. The touch sensing layer has an upper surface and a lower surface opposite to the upper surface. The second adhesive layer is disposed under the touch sensing layer. A thickness of the second adhesive layer is 50 μm. The polarizing film is disposed under the second adhesive layer. A thickness of the polarizing film is 46 μm. The organic light emitting display layer is disposed under the polarizing film. A thickness of the organic light emitting display layer is 35 μm. The support layer is disposed under the organic light emitting display layer. A thickness of the support layer is 38 μm. The third adhesive layer is disposed under the support layer. A thickness of the third adhesive layer is 50 μm. The substrate is disposed under the third adhesive layer. A thickness of the substrate is 30 μm. A plane located at half of the thickness of the touch sensing layer is defined as a center plane. The center plane is parallel to the upper surface and the lower surface, and the polarizing film is located at half of a total thickness of the touch display module.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings:

FIG. 1A schematically depicts a cross-sectional schematic diagram of a touch display module according to some embodiments of the present disclosure;

FIG. 1B schematically depicts a cross-sectional schematic diagram of the touch display module in FIG. 1A when being bent; and

FIG. 2 to FIG. 4C schematically and respectively depict cross-sectional schematic diagrams of touch display modules according to some other embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. Any examples of the use of the term discussed herein included in the description of the present specification are merely for illustrative purposes, and are not intended to limit the scope and meaning of the present disclosure or any exemplary term. Similarly, the present disclosure is not limited to the various embodiments described in this specification.

Further, spatially relative terms, such as “beneath,” “below,” “lower,” “above,” “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

As used herein, the singular forms “a”, “an”, and “the” are intended to include the plural forms as well, unless the context clearly indicates otherwise. It will be further understood that the terms “comprises” and/or “comprising”, or “includes” and/or “including”, or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” etc., may be used herein to describe various elements, these elements should not be limited by these terms. These terms are used to distinguish one element from another. For example, a first element could be termed a second element, and similarly, a second element could be termed a first element, without departing from the scope of the embodiments.

It will be understood that, as used herein, the term “and/or” includes any and all combinations of one or more of the associated listed items.

In the description herein and throughout the claims that follow, Young's modulus is the ratio of the force per unit cross-sectional area to a component's relative deformation when the component is within the “elastic limit”. It is used to specifically evaluate the ability of the material to resist deformation. The larger the Young's modulus, the better the ability to resist deformation.

In the description herein and throughout the claims that follow, Poisson's ratio represents the ratio of the absolute values of the lateral normal strain to the axial normal strain when the material is under tension or compression in one direction, which is also called the lateral deformation coefficient. It reflects the elastic constant of the material's lateral deformation. The smaller the Poisson's ratio, the better the ability to resist lateral deformation.

Reference will now be made in detail to the present embodiments of the invention, examples of which are illustrated in the accompanying drawings. Wherever possible, the same reference numbers are used in the drawings and the description to refer to the same or like parts.

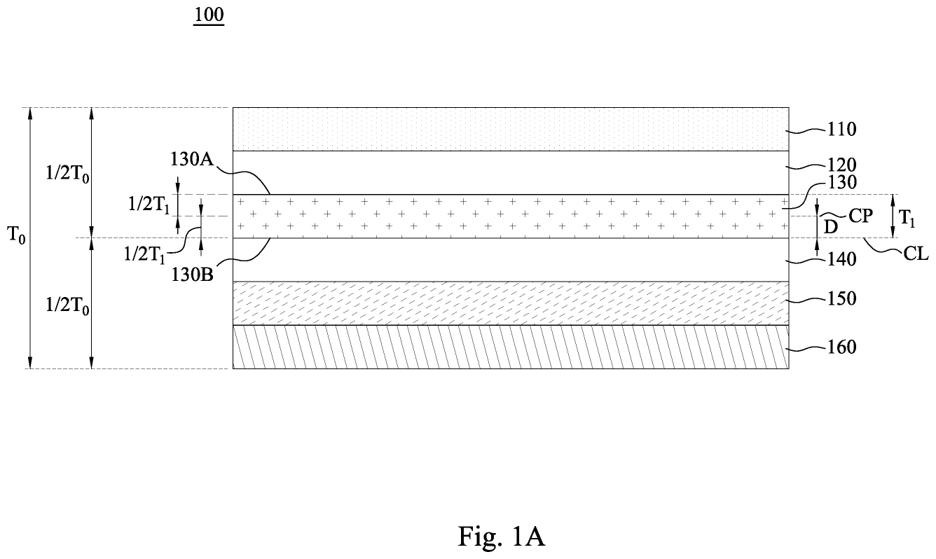

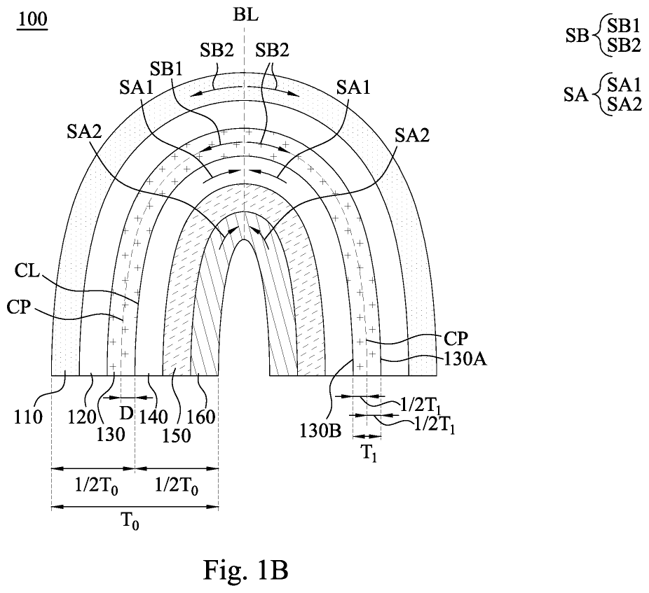

A description is provided with reference to FIG. 1A and FIG. 1B. FIG. 1A schematically depicts a cross-sectional schematic diagram of a touch display module 100 according to some embodiments of the present disclosure. The touch display module 100 includes a thin glass layer 110, an adhesive layer 120 disposed under the thin glass layer 110, a touch sensing layer 130 disposed under the adhesive layer 120, an adhesive layer 140 disposed under the touch sensing layer 130, a polarizing film 150 disposed under the adhesive layer 140, and an organic light emitting display layer 160 disposed under the polarizing film 150. In some embodiments of the present disclosure, through parameter adjustments by selecting the materials that are not easily deformed when being bent (such as materials within specific ranges of Young's modulus and Poisson's ratio), the order of components in the stack, the thicknesses of the components, etc., the damages caused by the stress to the touch display module 100 when being bent are reduced. The durability of the touch display module 100 is improved, so as to realize the bendable touch display module 100.

In greater detail, a description is provided with reference to FIG. 1 B. FIG. 1B schematically depicts a cross-sectional schematic diagram of the touch display module 100 in FIG. 1A when being bent, and the detailed force situation when the touch display module 100 is bent is also illustrated. First, a plane located at half of a total thickness TO of the touch display module 100 is defined as a stress neutral layer CL (parallel to the thin glass layer 110). Then, when the touch display module 100 is bent, the components on a compression side along a bending line BL (for the bending method of FIG. 1 B, the components below the stress neutral layer CL, such as the adhesive layer 140, the polarizing film 150, and the organic light emitting display layer 160) bear a compressive stress SA. In addition, the farther away from the stress neutral layer CL, the greater the compressive stress SA that the component on the compression side bears; that is, a compressive stress SA2 is greater than a compressive stress SA1. Conversely, the components on a tensile side along the bending line BL (for the bending method of FIG. 1B, the components above the stress neutral layer CL, such as the thin glass layer 110, the adhesive layer 120, and the touch sensing layer 130) bear a tensile stress SB, and the farther away from the stress neutral layer CL, the greater the tensile stress SB that the component on the tensile side bears; that is, a tensile stress SB2 is greater than a tensile stress SB1.

Therefore, according to the above principle of stress distribution during bending, the stress neutral layer CL can be disposed in a component that is more fragile or important and needed to be specially protected (for example, the touch sensing layer 130 in FIG. 1A and FIG. 1B), so that the component to be specially protected bears less stress to reduce the stress damages during bending. Correspondingly, a material that can withstand greater stress is disposed at a position away from the stress neutral layer CL (for example, the thin glass layer 110) to avoid stress damages to other more fragile components in the touch display module 100 during bending. In some embodiments, the stress neutral layer CL is disposed in the touch sensing layer 130 (for example, as shown in FIG. 1A and FIG. 1B) or close to the touch sensing layer 130 (not shown). When the stress neutral layer CL is close to the touch sensing layer 130, the following situation can be defined in greater detail: a plane located at half of a vertical distance from an upper surface 130A to a lower surface 130B of the touch sensing layer 130 is defined as a center plane CP. The center plane CP is parallel to the upper surface 130A and the lower surface 130B, and a vertical distance D between the stress neutral layer CL and the center plane CP is less than twice a thickness T1 of the touch sensing layer 130.

In some embodiments, the Young's modulus of each of the thin glass layer 110, the touch sensing layer 130, the polarizing film 150, and the organic light emitting display layer 160 is greater than 2000 million pascals. If the Young's modulus is less than 2000 million pascals, deformation tends to occur due to stress during bending. In some embodiments, the Poisson's ratio of each of the thin glass layer 110, the touch sensing layer 130, the polarizing film 150, and the organic light emitting display layer 160 is less than 0.5. If the Poisson's ratio of the abovementioned components is greater than 0.5, lateral (that is, parallel to the direction of stress) deformation tends to be generated under stress. As a result, materials of the thin glass layer 110, the touch sensing layer 130, the polarizing film 150, and the organic light emitting display layer 160 are selected to be materials that corresponds to the above ranges of Young's modulus and Poisson's ratio, which can more effectively prevent the touch display module 100 from being damaged by stress when being bent (that is, the touch display module 100 is prevented from being damaged by the tensile stress and the compressive stress).

A further description of the material properties, thickness ranges, and the function of each of the components is provided as follows.

In some embodiments, the thin glass layer 110 may be a thin transparent inorganic glass layer (for example, ultra thin glass (UTG)). Ultra thin glass has a good moisture barrier property, which has oxygen permeability less than 0.01 milliliters (cc)/square meter×24 hours (hr) and has vapor permeability from 1×10⁻⁶ g/square meter×24 hours to 1×10⁻⁵ g/square meter×24 hours. Or, the thin glass layer 110 may be a thin transparent organic glass layer. The thin transparent organic glass layer may be a thin plastic glass layer, such as a transparent material including poly(methylmethacrylate) (PMMA), polyethylene (PE), polyvinyl chloride (PVC), polypropylene (PP), polyethylene terephthalate (PET), polyethylene naphthalate (PEN), polycarbonate (PC), polystyrene (PS), polyimide (PI), or a cyclo-olefin polymer (COP), etc.

In some embodiments, the thin glass layer 110 is located on the outermost side and away from the stress neutral layer CL, so the thin glass layer 110 needs to have better resistance to deformation caused by stress during bending (including anti-tensile strength and anti-compressive strength). For example, when the material of the thin glass layer 110 is PI, the Young's modulus is from 7100 million pascals to 7900 million pascals, such as 7100 million pascals, 7300 million pascals, 7500 million pascals, 7900 million pascals, or any value within the abovementioned intervals. When the material of the thin glass layer 110 is UTG, the Young's modulus is from 69000 million pascals to 77000 million pascals, such as 69000 million pascals, 72500 million pascals, 75000 million pascals, 77000 million pascals, or any value within the abovementioned intervals. In some embodiments, when the material of the thin glass layer 110 is PI or UTG, the Poisson's ratio is less than 0.3, for example, from 0.19 to 0.22, such as 0.19, 0.20, 0.21, 0.22, or any value within the abovementioned intervals.

In some embodiments, a thickness of the thin glass layer 110 is from 25 micrometers (μm) to 100 μm, for example, 25 μm, 30 μm, 40 μm, 50 μm, 60 μm, 70 μm, 80 μm, 100 μm, or any value within the abovementioned intervals.

In some embodiments, a material of the adhesive layer 120 and the adhesive layer 140 may be an optical clear adhesive (OCA). The adhesive layer 120 is used to absorb the mismatch between the thin glass layer 110 and the touch sensing layer 130 (due to the deviation of processing accuracy between the components, the deviation while matching is caused). The adhesive layer 140 is used to absorb the mismatch between the touch sensing layer 130 and the polarizing film 150. Additionally, through adjusting thicknesses of the adhesive layer 120 and the adhesive layer 140, the stress neutral layer CL can be adjusted to be located in a specific component (for example, the touch sensing layer 130 in FIG. 1A and FIG. 1 B).

In some embodiments, the thickness of the adhesive layer 120 is from 10 μm to 60 μm, for example, 10 μm, 20 μm, 30 μm, 40 μm, 50 μm, 60 μm, or any value within the abovementioned intervals. In some embodiments, the thickness of the adhesive layer 140 is from 40 μm to 60 μm, for example, 40 μm, 45 μm, 50 μm, 55 μm, 60 μm, or any value within the abovementioned intervals.

In some embodiments, the touch sensing layer 130 includes a circuit structure. Hence, when the touch sensing layer 130 bears an excessive stress, damages to the circuit structure (for example, circuit breakage or skewing) are caused, which reduces the performance of the touch display module 100. In some embodiments, by using the order and thicknesses of the components (it should be noted that the thicknesses of the components in the figures are only illustrative), the stress neutral layer CL is disposed in the touch sensing layer 130 (that is, the vertical distance D is less than or equal to half of the thickness T1), which reduces the stress that the touch sensing layer 130 bears during bending, for example, as shown in FIG. 1A and FIG. 1B.

In some embodiments, the circuit structure may include metal nanowires formed by coating a dispersion or an ink, and may include a metal circuit (for example, silver wire, copper wire, or a circuit structure in a form of a multilayer alloy, and the circuit structure in the form of the multilayer alloy may be, for example, molybdenum/aluminum/molybdenum, copper/nickel, titanium/aluminum/titanium, or molybdenum/chromium, etc.) formed by electroplating, electroless plating, or autocatalytic plating. In some embodiments, a detailed method of forming a touch sensing film layer made of metal nanowires includes: coating the dispersion or the ink having metal nanowires on a substrate, and drying the dispersion or the ink having metal nanowires to form on the substrate. After substances, including solvent, etc., in the dispersion or ink are volatilized, the metal nanowires are randomly distributed and fixed to a surface of the substrate to form the touch sensing layer 130, and the metal nanowires are in contact with one another. A continuous current path is provided to further form a conductive network. In some embodiments, the dispersion may be water, alcohol, ketone, ether, hydrocarbon, or an aromatic solvent (benzene, toluene, xylene, etc.). In one embodiment, the dispersion may include an additive, a surfactant, or a binder, such as carboxymethyl cellulose (CMC), hydroxyethyl cellulose (HEC), hydroxypropyl methylcellulose (HPMC), ester of sulfonic acid, ester of sulfuric acid, disulfonate, sulfosuccinate, phosphoric ester, or a fluorine-containing surfactant, etc.

It is noted that, as used herein, “metal nanowires” is a collective term that refers to a collection of metal wires comprising multiple metal elements, metal alloys, or metal compounds (including metal oxides). In addition to that, at least one cross-sectional dimension (that is, a diameter of a cross section) of a single metal nanowire is less than about 500 nanometers (nm), preferably less than about 100 nm, and more preferably less than about 50 nm. In some embodiments, the “wire” metal nanostructure mainly has a high aspect ratio, for example, between about 10 and 100,000. In greater detail, the aspect ratio (length: diameter of the cross section) of the metal nanowire may be greater than about 10, for example, greater than about 50, or greater than about 100. However, the present disclosure is not limited in this regard. In some embodiments, the metal nanowire may be any metal, including (but not limited to) silver, gold, copper, nickel, or gold-plated silver. Other terms, such as silk, fiber, tube, etc., are also within the scope of the embodiments of the present disclosure if they have the above dimension and high aspect ratio.

In some embodiments, a thickness of the touch sensing layer 130 is from 28 μm to 48 μm, for example, 28 μm, 33 μm, 38 μm, 43 μm, 48 μm, or any value within the abovementioned intervals.

In some embodiments, the polarizing film 150 may be a polyester film (PET film), or a tri-cellulose acetate film (TAC film), or a combination thereof.

In some embodiments, the Young's modulus of the polarizing film 150 may be 2700 million pascals, 2800 million pascals, 3000 million pascals, 3100 million pascals, or any value within the abovementioned intervals. In some embodiments, the Poisson's ratio of the polarizing film 150 may be 0.33, 0.34, 0.35, 0.36, 0.37, or any value within the abovementioned intervals.

In some embodiments, a thickness of the polarizing film 150 may be 43 μm, 44 μm, 45 μm, 46 μm, 47 μm, 48 μm, 49 μm, or any value within the abovementioned intervals.

In some embodiments, the organic light emitting display layer 160 is an organic light-emitting diode (OLED) having a multilayer organic film structure.

In some embodiments, the organic light emitting display layer 160 is located on the outermost side and away from the stress neutral layer CL, which is required for better resistance to stress during bending. For example, the Young's modulus of the organic light emitting display layer 160 may be 13000 million pascals, 13500 million pascals, 14000 million pascals, 14500 million pascals, 15000 million pascals, or any value within the abovementioned intervals. In some embodiments, the Poisson's ratio of the organic light emitting display layer 160 may be is 0.38, 0.39, 0.40, 0.41, 0.42, or any value within the abovementioned intervals.

In some embodiments, a thickness of the organic light emitting display layer 160 is 33 μm, 34 μm, 35 μm, 36 μm, or any value within the abovementioned intervals.

In some embodiments, through the combination of the above suitable materials and thicknesses, the electrical test shows that a time constant of a resistor-capacitor (RC) (the required time for the terminal voltage to increase to 63.2% of the maximum voltage during the charging process of the capacitor) can be less than 1400 nanoseconds after the touch sensing layer 130 has been bent for 3500 cycles, which meets the current electrical specification. For example, when the thicknesses of the adhesive layer 120 and the adhesive layer 140 are both 50 μm, the time constant of the resistor-capacitor of the touch display module 100 is 1310.90 nanoseconds. When the thin glass layer 110 is an organic polymer film, the time constant of the resistor-capacitor of the touch display module 100 is 1256.55 nanoseconds.

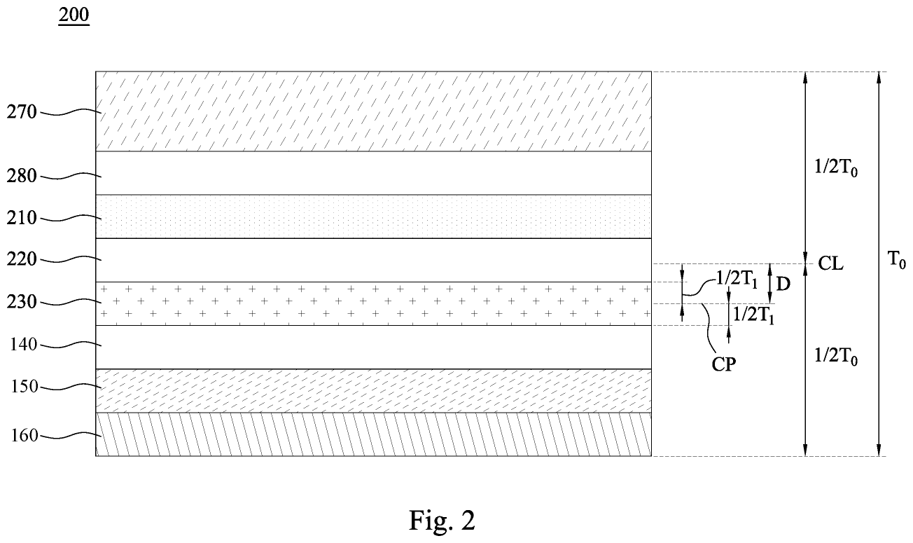

In some other embodiments, an additional component may be selectively disposed on the touch display module 100 (for example, as shown in the subsequent FIG. 2 to FIG. 4C) to disperse the stress borne by the touch display module 100 so as to extend the durability of use.

A description is provided with reference to FIG. 2. FIG. 2 depicts a cross-sectional schematic diagram of a touch display module 200 according to some other embodiments of the present disclosure. The materials, characteristic requirements, and thickness ranges of the components used in FIG. 2 may be basically the same as or similar to those in FIG. 1A.

A difference between FIG. 2 and FIG. 1A lies in that FIG. 2 further includes a cover plate 270 disposed on the thin glass layer 210 and an adhesive layer 280 disposed between the cover plate 270 and the thin glass layer 210. In addition, in FIG. 2 the stress neutral layer CL is located in the adhesive layer 220 and is close to a touch sensing layer 230 (that is, the vertical distance D between the stress neutral layer CL and the center plane CP is less than twice the thickness T1 of the touch sensing layer 230), so that the touch sensing layer 230 bears a relatively small stress during bending. In FIG. 2, the vertical distance D is greater than ½ of the thickness T1 and is less than the thickness T1, less than 1.5 times the thickness T1, or less than 2 times the thickness T1.

The cover plate 270 in FIG. 2 is used to protect the touch display module 200 and has the same function as the thin glass layer 110 in FIG. 1A. The material of the cover plate 270 may be the same as or similar to the thin glass layer 110 in FIG. 1A. The adhesive layer 280 in FIG. 2 is used to buffer stress and adjust a position of the stress neutral layer CL. The material of the adhesive layer 280 may be the same as or similar to the adhesive layer 120 and the adhesive layer 140 in FIG. 1A.

In some embodiments, when cooperating with the cover plate 270, the material of the thin glass layer 210 can be specially selected as UTG. Using the high Young's modulus of UTG, such as greater than 65000 million pascals, (for example, the Young's modulus of UTG is 65×1×10⁹ pascals (65 G pascals), or 69,000 million pascals to 77,000 million pascals), endows UTG with the characteristic of not being deformed easily when bearing a force. Not only can the thin glass layer 210 made of UTG better protect the internal components (such as the touch sensing layer 230), but it also has better stiffness (force of unit resistance torque generated under stress in the range of elastic deformation when being bent), which helps to assist the touch display module 200 to quickly restore its original state after being bent.

In some embodiments, thicknesses of the thin glass layer 210 and the adhesive layer 220 can be adjusted correspondingly depending on practical needs. In some embodiments, when the thickness of the thin glass layer 210 is from 60 μm to 80 μm, the thickness of the adhesive layer 220 is from 10 μm to 35 μm. In some other embodiments, when the thickness range of the thin glass layer 210 is reduced, the thickness of the adhesive layer 220 can be increased compensatorily correspondingly. For example, when the thickness of the thin glass layer 210 is from 40 μm to 60 μm, the thickness of the adhesive layer 220 is from 36 μm to 60 μm so as to control the position of the stress neutral layer CL.

In some embodiments, a thickness of the cover plate 270 is from 50 μm to 70 μm, for example, 50 μm, 60 μm, 70 μm, or any value within the abovementioned intervals. The thickness of the cover plate 270 is at least 50 μm, which can be used to provide better protection for the touch display module 200. The thickness of the cover plate 270 is at most 70 μm to prevent the cover plate 270 from consuming too much space.

In some embodiments, a thickness of the adhesive layer 280 is from 40 μm to 60 μm, for example, 40 μm, 50 μm, 60 μm, or any value within the abovementioned intervals. The thickness of the adhesive layer 280 is at least 40 μm, which can better buffer the stress during bending. The thickness of the adhesive layer 280 is at most 70 μm to prevent the adhesive layer 280 from consuming too much space.

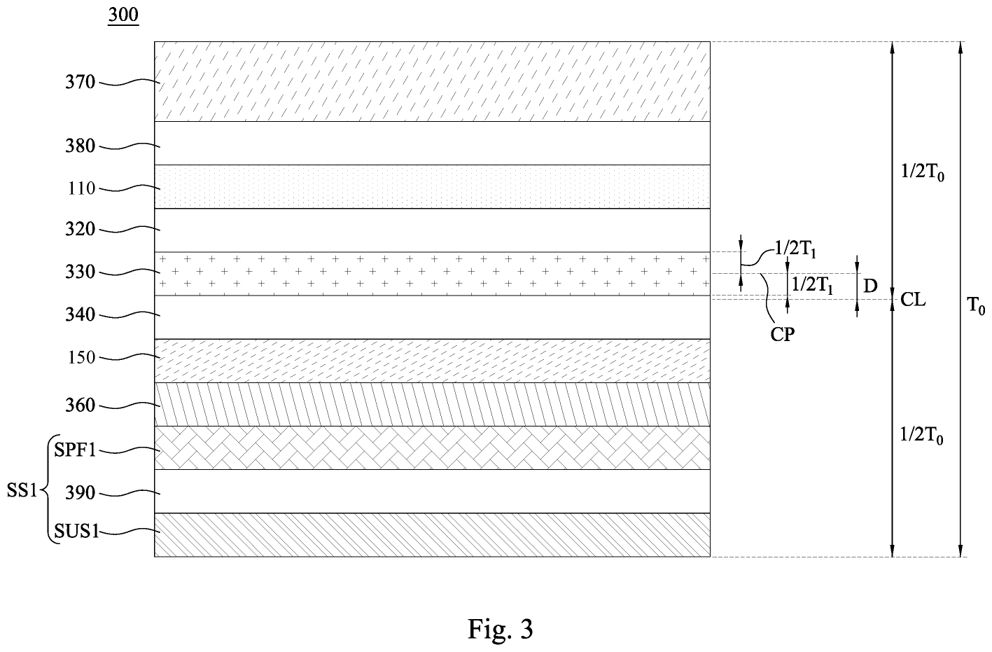

A description is provided with reference to FIG. 3. FIG. 3 illustratively depicts a cross-sectional schematic diagram of a touch display module 300 according to still some other embodiments of the present disclosure.

The materials, characteristic requirements, and thickness ranges of the components used in FIG. 3 may be basically the same as or similar to those in FIG. 2.

A difference between FIG. 3 and FIG. 2 lies in that FIG. 3 further includes a support structure SS1 disposed under an organic light emitting display layer 360. The support structure SS1 sequentially includes a support layer SPF1 disposed under the organic light emitting display layer 360, an adhesive layer 390 disposed under the support layer SPF1, and a substrate SUS1 disposed under the adhesive layer 390 from top to bottom. Additionally, in FIG. 3 the stress neutral layer CL is located in an adhesive layer 340 and is similarly close to a touch sensing layer 330 (that is, the vertical distance D between the stress neutral layer CL and the center plane CP is less than twice the thickness T1 of the touch sensing layer 330), so that the touch sensing layer 330 bears a relatively small stress during bending. In FIG. 3, the vertical distance D is greater than ½ the thickness T1 and is less than the thickness T1, less than 1.5 times the thickness T1, or less than 2 times the thickness T1.

Based on the similar functions of buffering and adjusting a position of the stress neutral layer CL, a material of the adhesive layer 390 may be the same as or similar to an adhesive layer 320, an adhesive layer 340, and an adhesive layer 380. A thickness of the adhesive layer 390 is from 40 μm to 60 μm, for example, 40 μm, 45 μm, 50 μm, 55 μm, 60 μm, or any value within the abovementioned intervals.

In some embodiments, the support layer SPF1 is mainly used for supporting and protecting the organic light emitting display layer 360, and the material of the support layer SPF1 may include a high molecular polymer film, such as a PI film.

In some embodiments, the Young's modulus of the support layer SPF1 is from 3500 million pascals to 3900 million pascals, such as 3500 million pascals, 3600 million pascals, 3700 million pascals, 3800 million pascals, 3900 million pascals, or any value within the abovementioned intervals. In some embodiments, the Poisson's ratio of the support layer SPF1 is from 0.38 to 0.42, such as 0.38, 0.39, 0.40, 0.41, 0.42, or any value within the abovementioned intervals.

In some embodiments, a thickness of the support layer SPF1 is from 28 μm to 48 μm, such as 28 μm, 33 μm, 38 μm, 43 μm, 48 μm, or any value within the abovementioned intervals.

In some embodiments, the substrate SUS1 and the cover plate 370 are respectively disposed on outermost and opposite sides of the touch display module 300, which together bears a greater stress during bending. Therefore, the substrate SUS1 can include a material that has resistance to deformation caused by stress during bending (for example, Young's modulus and Poisson's ratio) similar to the cover plate 370, such as a thin transparent inorganic glass layer (for example, ultra thin glass (UTG)) or a thin transparent organic glass layer.

In greater detail, in some embodiments, the Young's modulus of the substrate SUS1 is from 76000 million pascals to 84000 million pascals, such as 76000 million pascals, 77000 million pascals, 78000 million pascals, 79000 million pascals, 80000 million pascals, 81000 million pascals, 82000 million pascals, 83000 million pascals, 84000 million pascals, or any value within the abovementioned intervals. In some embodiments, the Poisson's ratio of the substrate SUS1 is from 0.27 to 0.31, such as 0.27, 0.28, 0.29, 0.30, 0.31, or any value within the abovementioned intervals.

In some embodiments, a thickness of the substrate SUS1 is from 20 μm to 40 μm, such as 20 μm, 25 μm, 30 μm, 35 μm, 40 μm, or any value within the abovementioned intervals

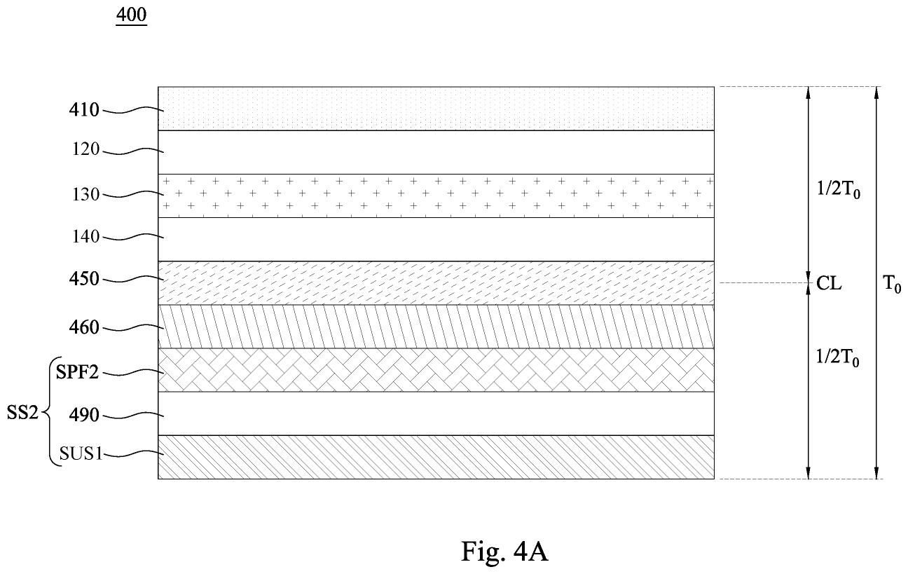

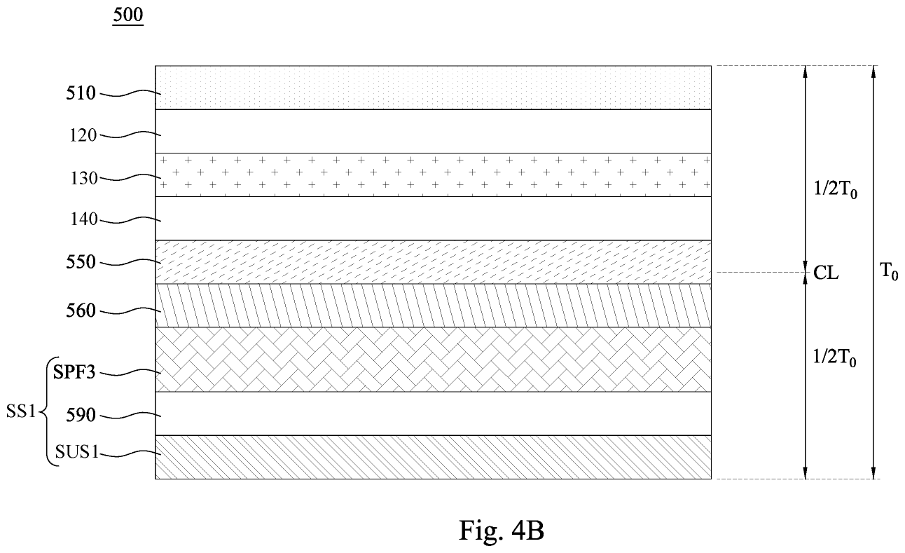

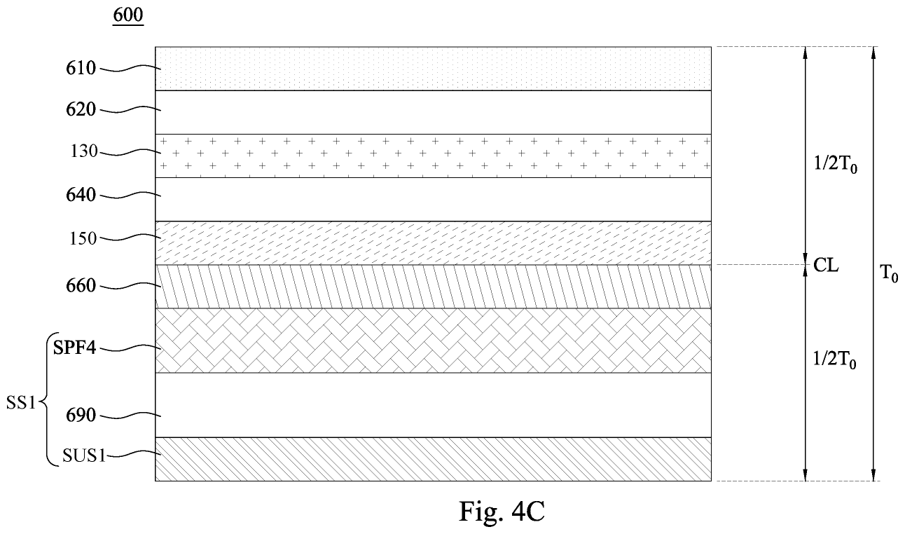

A description is provided with reference to FIG. 4A to FIG. 4C. FIG. 4A to FIG. 4C illustratively depict cross-sectional schematic diagrams of touch display modules (a touch display module 400 of FIG. 4A, a touch display module 500 of FIG. 4B, and a touch display module 600 of FIG. 4C) according to yet some other embodiments of the present disclosure. That is, on the basis of the touch display module 100 of FIG. 1A, support structures are further disposed under the organic light emitting display layer (for example, a support structure SS2 in FIG. 4A is disposed under an organic light emitting display layer 460).

The materials and characteristic requirements of the components used in FIG. 4A to FIG. 4C and the thickness ranges of most of the components may be basically the same as or similar to those in FIG. 3. A common difference between FIG. 4A to FIG. 4C and FIG. 3 lies in that there are no cover plate and adhesive layer disposed on the thin glass layer (a thin glass layer 410 of FIG. 4A, a thin glass layer 510 of FIG. 4B, and a thin glass layer 610 of FIG. 4C) in FIG. 4A to FIG. 4C.

It is noted that in order to protect polarizing films (a polarizing film 450 of FIG. 4A and a polarizing film 550 of FIG. 4B), both the stress neutral layers CL of the touch display module 400 of FIG. 4A and the touch display module 500 of FIG. 4B are located in the polarizing films (the polarizing film 450 of FIG. 4A and the polarizing film 550 of FIG. 4B) to minimize bending stresses born by the polarizing films (the polarizing film 450 of FIG. 4A and the polarizing film 550 of FIG. 4B).

In some embodiments, a thickness of a support layer SPF2 in FIG. 4A is from 28 μm to 48 μm. A thickness of an adhesive layer 490 is from 40 μm to 60 μm. The thicknesses are basically the same as or similar to the thicknesses of the support layer SPF1 and the adhesive layer 390 in FIG. 3.

In greater detail, a difference between FIG. 4B and FIG. 4A lies in that a thickness of a support layer SPF3 in FIG. 4B is increased as compared with that of the support layer SPF2 in FIG. 4A to improve the supportive ability of the support layer SPF3 relative to the support layer SPF2 and the effect of protecting an organic light emitting display layer 560. In some embodiments, as compared with FIG. 4A, the thickness of the support layer SPF3 in FIG. 4B is increased to 65 μm to 85 μm, such as 65 μm, 70 μm, 75 μm, 80 μm, 85 μm, or any value within the abovementioned intervals.

On the contrary, in FIG. 4C in order to reduce the stress born by an organic light emitting display layer 660, the stress neutral layer CL of the touch display module 600 in FIG. 4C is located in the organic light emitting display layer 660. As compared with FIG. 4B, a thickness of an adhesive layer 690 in the touch display module 600 of FIG. 4C is increased as compared with that of an adhesive layer 590 in FIG. 4B. By increasing the thickness of the adhesive layer 690, the stress neutral layer CL is located in the organic light emitting display layer 660 to protect the organic light emitting display layer 660.

In some embodiments, a thickness of a support layer SPF4 in FIG. 4C may be the same as or similar to the thicknesses of the support layer SPF3 in FIG. 4B, and the thickness of the adhesive layer 690 may be increased to 60 μm to 80 μm, such as 60 μm, 65 μm, 70 μm, 75 μm, 80 μm, 85 μm, or any value within the abovementioned intervals. It is noted that, in some other embodiments, it is also possible to adjust a thickness of an adhesive layer 620 or an adhesive layer 640 together to similarly achieve the objective that the stress neutral layer CL is located in the organic light emitting display layer 660.

In some embodiments, the touch display modules (such as the touch display module 100 of FIG. 1A to the touch display module 600 of FIG. 4C) can be further assembled with other electronic components to form an electronic device, including but not limited to a mobile device (a mobile phone, a tablet computer, or a laptop computer) or a wearable device (a smart watch, smart glasses, smart clothing, or smart shoes), etc.

In summary, the touch display module according to some embodiments of the present disclosure adjusts the stress distribution through adjusting the order of components in the stack and the thicknesses of the components. In addition to that, the stress neutral layer (half the total thickness of the touch display module) is specially designed in the component to be specially protected to reduce the stress born by the component to be specially protected during bending. As a result, the bendable touch display module is realized.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A touch display module comprising:
a cover plate, wherein a thickness of the cover plate is from 50 μm to 70 μm;
a first adhesive layer disposed under the cover plate, wherein a thickness of the first adhesive layer is from 40 μm to 60 μm;
a thin glass layer disposed under the first adhesive layer, wherein a thickness of the thin glass layer is from 40 μm to 80 μm;
a second adhesive layer disposed under the thin glass layer, wherein a thickness of the second adhesive layer is from 10 μm to 60 μm;
a touch sensing layer disposed under the second adhesive layer, wherein a thickness of the touch sensing layer is from 28 μm to 48 μm, and the touch sensing layer has an upper surface and a lower surface opposite to the upper surface;
a third adhesive layer disposed under the touch sensing layer, wherein a thickness of the third adhesive layer is from 40 μm to 60 μm;
a polarizing film disposed under the third adhesive layer, wherein a thickness of the polarizing film is from 36 μm to 76 μm; and
an organic light emitting display layer disposed under the polarizing film, wherein a thickness of the organic light emitting display layer is from 40 μm to 60 μm;
wherein a plane located at half of the touch sensing layer is defined as a center plane, the center plane is parallel to the upper surface and the lower surface, and the touch sensing layer is located at half of a total thickness of the touch display module.

2. The touch display module of claim 1, wherein Young's modulus of the thin glass layer is greater than 65000 million pascals.

3. The touch display module of claim 1, wherein a plane located at half of the total thickness of the touch display module is defined as a stress neutral layer, and a vertical distance between the stress neutral layer and the center plane is less than half of the thickness of the touch sensing layer.

4. The touch display module of claim 1, wherein the thickness of the thin glass layer is from 60 μm to 80 μm, and the thickness of the second adhesive layer is from 10 μm to 35 μm.

5. The touch display module of claim 1, wherein the thickness of the thin glass layer is from 40 μm to 60 μm, and the thickness of the second adhesive layer is from 36 μm to 60 μm.

6. The touch display module of claim 5, further comprising:
a support layer disposed under the organic light emitting display layer, wherein a thickness of the support layer is from 28 μm to 85 μm;
a fourth adhesive layer disposed under the support layer, wherein a thickness of the fourth adhesive layer is from 40 μm to 60 μm; and
a substrate disposed under the fourth adhesive layer, wherein a thickness of the substrate being from 20 μm to 40 μm.

7. The touch display module of claim 1, wherein Poisson's ratio of the thin glass layer is less than 0.3.

8. The touch display module of claim 1, wherein a time constant of a resistor-capacitor of the touch sensing layer is less than 1400 nanoseconds.

9. A touch display module comprising:
a thin glass layer, wherein a thickness of the thin glass layer is 50 μm;
a first adhesive layer disposed under the thin glass layer, wherein a thickness of the first adhesive layer is 50 μm;
a touch sensing layer disposed under the first adhesive layer, wherein a thickness of the touch sensing layer is 38 μm, and the touch sensing layer has an upper surface and a lower surface opposite to the upper surface;
a second adhesive layer disposed under the touch sensing layer, wherein a thickness of the second adhesive layer is 50 μm;
a polarizing film disposed under the second adhesive layer, wherein a thickness of the polarizing film is 46 μm;
an organic light emitting display layer disposed under the polarizing film, wherein a thickness of the organic light emitting display layer is 35 μm;
a support layer disposed under the organic light emitting display layer, wherein a thickness of the support layer is 38 μm;
a third adhesive layer disposed under the support layer, wherein a thickness of the third adhesive layer is 50 μm; and
a substrate disposed under the third adhesive layer, wherein a thickness of the substrate is 30 μm;
wherein a plane located at half of the thickness of the touch sensing layer is defined as a center plane, the center plane is parallel to the upper surface and the lower surface, and the polarizing film is located at half of a total thickness of the touch display module.

10. The touch display module of claim 9, wherein Young's modulus of the thin glass layer is greater than 65000 million pascals.

11. The touch display module of claim 9, wherein a plane located at half of the total thickness of the touch display module is defined as a stress neutral layer, and a vertical distance between the stress neutral layer and the center plane is less than twice the thickness of the touch sensing layer.

12. A touch display module comprising:
a cover plate, wherein a thickness of the cover plate is 50 μm;
a first adhesive layer disposed under the cover plate, wherein a thickness of the first adhesive layer is 50 μm;
a touch sensing layer disposed under the first adhesive layer, wherein a thickness of the touch sensing layer is 38 μm, and the touch sensing layer has an upper surface and a lower surface opposite to the upper surface;
a second adhesive layer disposed under the touch sensing layer, wherein a thickness of the second adhesive layer is 50 μm;
a polarizing film disposed under the second adhesive layer, wherein a thickness of the polarizing film is 46 μm;
an organic light emitting display layer disposed under the polarizing film, wherein a thickness of the organic light emitting display layer is 35 μm;
a support layer disposed under the organic light emitting display layer, wherein a thickness of the support layer is 38 μm;
a third adhesive layer disposed under the support layer, wherein a thickness of the third adhesive layer is 50 μm; and
a substrate disposed under the third adhesive layer, wherein a thickness of the substrate is 30 μm;
wherein a plane located at half of the thickness of the touch sensing layer is defined as a center plane, the center plane is parallel to the upper surface and the lower surface, and the polarizing film is located at half of a total thickness of the touch display module.
